(19) United States
(12) Patent Application Publication
(10) Pub. No.: US 2023/0134439 A1
(43) Pub. Date: May 4, 2023

(54) DISPLAY DEVICE

(71) Applicants: SONY SEMICONDUCTOR SOLUTIONS CORPORATION, KANAGAWA (JP); SONY GROUP CORPORATION, TOKYO (JP)

(72) Inventors: YU KATO, KANAGAWA (JP); TAKASHI YAMAZAKI, TOKYO (JP)

(21) Appl. No.: 17/912,020

(22) PCT Filed: Mar. 30, 2021
(86) PCT No.: PCT/JP2021/013689

§ 371 Date: Sep. 15, 2022

(30) Foreign Application Priority Data
Mar. 31, 2020 (JP) 2020-063352

(51) Int. Cl. H10K 50/822; H10K 59/122; H10K 50/824

(52) U.S. Cl. CPC H01L 51/5225; H01L 27/3246; H01L 51/5228

(57) ABSTRACT

In a display device, sub-pixels each having a structure in which a first electrode and a second electrode are laminated with an organic compound layer having a light emitting layer interposed therebetween are provided in such an arrangement pattern that the sub-pixels are separated from each other two-dimensionally, and the second electrode is patterned so as to straddle the sub-pixels and be connected between the sub-pixels, and includes a plurality of branching portions connected to each other, and the branching portions are two-dimensionally arranged.

### TECHNICAL FIELD

The present disclosure relates to a display device, and particularly to a display device having a structure in which a first electrode, an organic compound layer, and a second electrode are laminated.

### BACKGROUND ART

As a display device using a light emitting element such as an organic EL element, a display device having a structure in which an organic compound layer including a light emitting layer and a second electrode are laminated on a first electrode provided in an arrangement pattern separated in a manner corresponding to units of sub-pixels constituting one pixel is known. The layers such as the organic compound layer and the second electrode are patterned by a formation method such as a method using a vapor deposition technique, a method using a printing technique, a method using etching, or a method using photolithography.

The pattern of the organic compound layer and the second electrode is determined in accordance with a formation pattern of one or a plurality of types of sub-pixels constituting one pixel. For example, in the technique of Patent Document 1, the pattern of the organic compound layer and the second electrode is a stripe-shaped pattern straddling the sub-pixels.

### CITATION LIST

### Patent Document

Patent Document 1: WO 2017/212797 A

### SUMMARY OF THE INVENTION

### Problems to be Solved by the Invention

The technique of Patent Document 1 has room for improvement in terms of effectively suppressing occurrence of a line defect in an image displayed on a display device even in a case where a defect occurs in a second electrode also functioning as a wiring.

The present disclosure has been made in view of the above points, and an object of the present disclosure is to provide a display device capable of suppressing occurrence of a line defect in an image displayed on the display device even in a case where a defect occurs in a second electrode.

### Solutions to Problems

The present disclosure provides, for example, a display device in which sub-pixels each having a structure in which a first electrode and a second electrode are laminated with an organic compound layer having a light emitting layer interposed therebetween are provided in such an arrangement pattern that the sub-pixels are separated from each other, and the second electrode is patterned so as to straddle the sub-pixels and be connected between the sub-pixels, and includes a plurality of branching portions connected to each other, and the branching portions are two-dimensionally arranged.

### BRIEF DESCRIPTION OF DRAWINGS

FIG. 1A is a plan view illustrating a schematic configuration of one embodiment of a display device.

FIG. 1B is a cross-sectional view illustrating a schematic configuration on a cross section taken along line IB-IB in FIG. 1A.

FIG. 2 is a cross-sectional view illustrating a schematic configuration on a cross section taken along line II-II in FIG. 1A.

FIG. 3 is a diagram illustrating an example of an energized state of a second electrode of the display device.

FIG. 4 is a cross-sectional view illustrating a schematic configuration of one embodiment of an auxiliary electrode of the display device.

FIG. 5A is a plan view illustrating one embodiment of a method of manufacturing a display device. FIG. 5B is a cross-sectional view illustrating a schematic configuration on a cross section taken along line VB-VB in FIG. 5A.

FIG. 6A is a plan view illustrating one embodiment of a method of manufacturing a display device. FIG. 6B is a cross-sectional view illustrating a schematic configuration on a cross section taken along line VIB-VIB in FIG. 6A.

FIG. 7A is a plan view illustrating one embodiment of a method of manufacturing a display device. FIG. 7B is a cross-sectional view illustrating a schematic configuration on a cross section taken along line VIIB-VIIB in FIG. 7A.

FIG. 8A is a plan view illustrating one embodiment of a method of manufacturing a display device. FIG. 8B is a cross-sectional view illustrating a schematic configuration on a cross section taken along line VIIIB-VIIIB in FIG. 8A.

FIG. 9A is a plan view illustrating a schematic configuration of one modification of a display device. FIG. 9B is a cross-sectional view illustrating a schematic configuration on a cross section taken along line IXB-IXB in FIG. 9A.

FIG. 10A is a plan view illustrating a schematic configuration of one modification of a display device. FIG. 10B is a cross-sectional view illustrating a schematic configuration on a cross section taken along line XB-XB in FIG. 10A.

FIG. 11A is a plan view illustrating a schematic configuration of one modification of a display device. FIG. 11B is a cross-sectional view illustrating a schematic configuration on a cross section taken along line XIB-XIB in FIG. 11A.

FIGS. 12A and 12B are plan views illustrating one embodiment of the second electrode.

FIGS. 13A, 13B, and 13C are plan views illustrating one embodiment of the second electrode.

FIG. 14 is a diagram illustrating an example of an energized state of a second electrode of a conventional display device.

### MODE FOR CARRYING OUT THE INVENTION

Hereinafter, an embodiment and others according to the present disclosure will be described with reference to the drawings. Note that the description will be given in the following order. In the present specification and the drawings, constituent elements having substantially identical functional configurations are given identical reference signs, and repeated description thereof will be omitted.

Note that the description will be given in the following order.

1. Display device

2. Method of manufacturing display device

3. Modification of display device

The following description is a preferred specific example of the present disclosure, and the content of the present disclosure is not limited to the embodiment and others.

[1. Display Device]

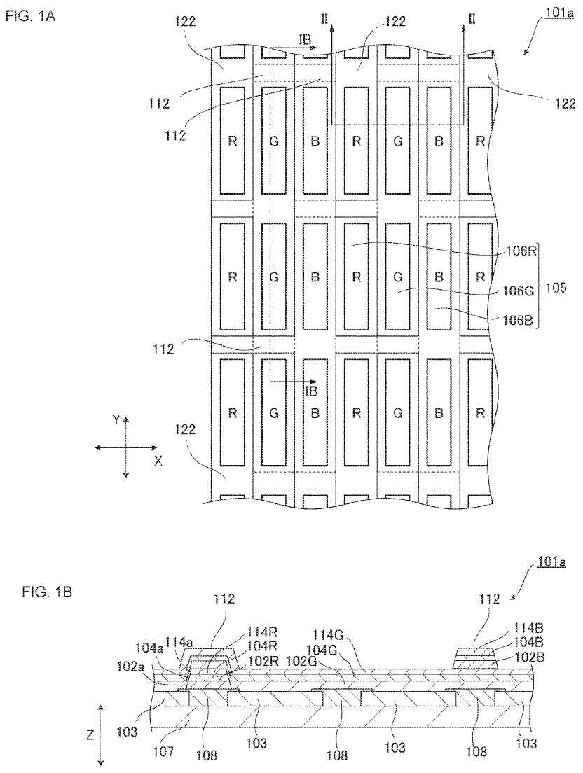

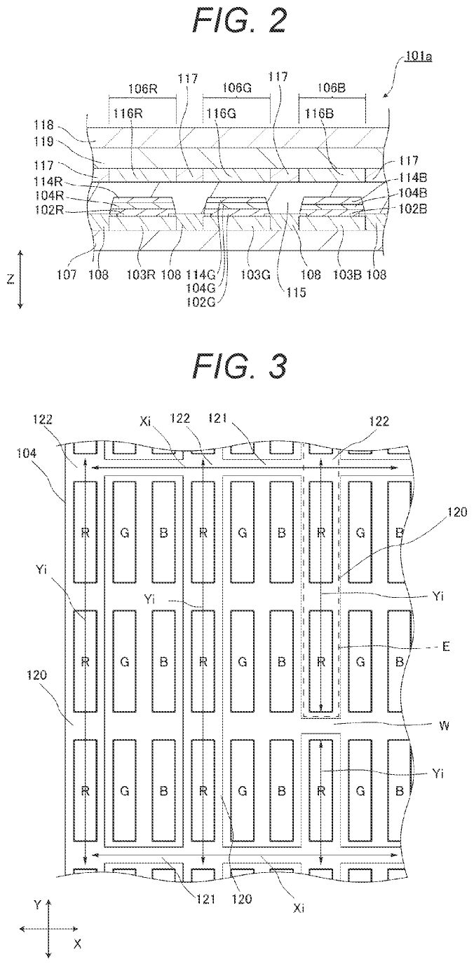

A display device 101a according to one embodiment of the present disclosure includes an organic compound layer 102 (102R, 102G, and 102B in FIGS. 1B and 2 and other drawings) having a light emitting layer, as illustrated in FIGS. 1A, 1B, and 2 and other drawings. A first electrode 103 (103R, 103G, and 103B in FIGS. 1B and 2 and other drawings) and a second electrode 104 (104R, 104G, and 104B in FIGS. 1B and 2 and other drawings) are laminated with the organic compound layer 102 interposed therebetween. Note that, for convenience of description, a laminating direction in which the first electrode 103, the organic compound layer 102, and the second electrode 104 are laminated in the display device 101a is defined as an up-down direction (Z direction in FIGS. 1B and 2). A direction from the first electrode 103 toward the second electrode 104 in the display device 101a is defined as an upward direction, and a direction opposite to the upward direction is defined as a downward direction. Furthermore, in FIGS. 1A and 1B, for convenience of description, description of a layer or a member formed on a protective layer 114, which will be described later, is omitted. The same applies to each of FIGS. 3 to 11 and 14. Furthermore, relative magnitude ratios of sizes and thicknesses of layers illustrated in FIGS. 1A, 1B, and 2 are described for convenience, and do not define actual magnitude ratios. As for the definition concerning the up-down direction and the magnitude ratios, the same applies to each of FIGS. 3 to 14.

In the display device 101a, a pixel region R and a non-pixel region U deviated from the pixel region R are provided, and pixels 105 arranged two-dimensionally are provided in the pixel region R. Each of the pixels 105 includes one or a plurality of types of sub-pixels 106. Therefore, the sub-pixels 106 are provided in the pixel region R. The sub-pixels 106 are provided in such an arrangement pattern that the sub-pixels 106 are separated from each other. Each of the sub-pixels 106 has a laminated structure in which the first electrode 103, the organic compound layer 102, and the second electrode 104 are laminated. The sub-pixels 106 illustrated in the example of FIG. 1A and other drawings are provided in such an arrangement pattern that the sub-pixels 106 are separated from each other two-dimensionally. In the present specification, the “two-dimensionally” indicates expansion in a direction of a predetermined plane.

### (Types of Sub-Pixels)

Examples of a criterion for determining the types of the sub-pixels 106 include differences in color of emitted light, thickness of the organic compound layer 102, structure of the organic compound layer 102, combinations thereof, and the like. In a case where a criterion for determining the types of the sub-pixels 106 is a difference in color of emitted light, for example, a case where the sub-pixels 106 include three types: red sub-pixels 106R, green sub-pixels 106G, and blue sub-pixels 106B as the sub-pixels 106 having different emitted light colors as described above can be exemplified.

The following describes, as an example, a case where the display device 101a includes, as the sub-pixels 106, three types of sub-pixels: sub-pixels (referred to as red sub-pixels 106R) from which red light is emitted, sub-pixels (referred to as green sub-pixels 106G) from which green light is emitted, and sub-pixels (referred to as blue sub-pixels 106B) from which blue light is emitted, as illustrated in FIGS. 1A, 1B, and 2. In the example of FIG. 1A, a single pixel 105 includes a combination of these three types of sub-pixels 106R, 106G, and 106B. However, this does not limit a combination of colors of the sub-pixels 106 constituting the pixel 105 to the combination of three colors of red, green, and blue in a case where the pixel 105 includes a plurality of types of sub-pixels 106. Note that, in FIG. 1A, portions denoted by letters R, G, and B are portions corresponding to the sub-pixels 106R, the sub-pixels 106G, and the sub-pixels 106B, respectively. The same applies to each of FIGS. 3 and 5 to 13. Note that, in the present specification, the sub-pixel 106R, the sub-pixel 106G, and the sub-pixel 106B may be collectively referred to as sub-pixels 106 in a case where types such as color types are not particularly distinguished.

### (Arrangement Pattern of Sub-Pixels)

In the example of FIG. 1A, the arrangement pattern of the sub-pixels 106 of each type is a stripe pattern, and the sub-pixels 106 of each type are arranged at positions shifted from each other. Specifically, as for the red sub-pixels 106R, one section (hereinafter referred to as a unit section) of the sub-pixels 106R is provided in an elongated rectangular shape, and the unit sections of the sub-pixels 106R are two-dimensionally arranged in a longitudinal direction (the Y direction in FIG. 1A) of the unit sections and a direction (the X direction in FIG. 1A) orthogonal to the longitudinal direction. The same applies to the green sub-pixels 106G and the blue sub-pixels 106B. Furthermore, the red sub-pixels 106R, the green sub-pixels 106G, and the blue sub-pixels 106B are provided at positions shifted from each other in the X direction.

### (First Electrode)

In the display device 101a, the first electrode 103 is provided on a substrate 107.

The first electrode 103 is provided in a pattern (patterned) so as to have an arrangement corresponding to the arrangement pattern of the sub-pixels 106, and is provided so as to be two-dimensionally separated in a manner corresponding to the unit sections of the sub-pixels 106. In the example of FIGS. 1A, 1B, and 2, three types of first electrodes 103R for red, 103G for green, and 103B for blue are provided corresponding to the three types of sub-pixels 106R, 106G, and 106B, respectively. Note that, in the present specification, the first electrode 103R, the first electrode 103G, and the first electrode 103B may be collectively referred to as the first electrode 103 in a case where types such as color types are not particularly distinguished.

On the substrate 107, a circuit such as a drive transistor for driving the display device 101a is provided (not illustrated). The circuit is electrically connected to the first electrode 103, and a state of energization to the first electrode 103 is controlled.

An insulating layer 108 having an opening 109 is provided between adjacent first electrodes 103. The opening 109 of the insulating layer 108 is provided at positions where the first electrode 103 is provided in plan view of the display device 101a. The openings 109 are provided in a pattern corresponding to the arrangement pattern of the sub-pixels 106, and one section of the opening 109 defines the unit section of the sub-pixel 106. Note that the opening 109 may be provided so as to match the shape of the first electrode 103 or may be provided on the first electrode 103 as illustrated in the example of FIG. 1B. In a case where the opening 109 is provided on the first electrode 103, the insulating layer 108 is provided so as to cover side end surfaces and an outer edge portion on an upper surface side of the first electrode 103 and to ride on the upper surface side of the first electrode 103. Note that the plan view of the display device 101a indicates a case where a line-of-sight direction is the up-down direction.

The first electrode 103 functions as an electrode that controls light emission of the sub-pixels 106 in combination with the second electrode 104, which will be described later. In a case where the first electrode 103 is an anode electrode, the second electrode 104 is a cathode electrode, and in a case where the first electrode 103 is a cathode electrode, the second electrode 104 is an anode electrode.

In a case where the first electrode 103 is an anode electrode, the first electrode 103 is preferably formed of a metal having a high work function, such as platinum, gold, silver, chromium, tungsten, nickel, copper, iron, cobalt, or tantalum. Alternatively, the first electrode 103 may be formed of an alloy of the metals having a high work function described above, and may be, for example, formed of an Ag—Pb—Cu alloy or an Al—Nd alloy.

However, this does not prohibit the first electrode 103 from being formed of a metal having a small work function. For example, the first electrode 103 may be formed of a conductive material that is a metal having a small work function and has a high light reflectance, such as aluminum or an alloy containing aluminum. In this case, the first electrode 103 can be used as an anode electrode by providing a hole injection layer in the laminated structure forming the sub-pixel 106 to improve a hole injection characteristic.

The first electrode 103 may be formed of an indium oxide, an indium-tin oxide (ITO, examples of which include an Sn-doped indium oxide, a crystalline ITO, and an amorphous ITO), an indium-zinc oxide (IZO), an indium-gallium oxide (IGO), an indium-doped gallium-zinc oxide (IGZO), IFO (F-doped In₂O₃), ITiO (Ti-doped In₂O₃), InSnZnO, a tin oxide (SnO₂), ATO (Sb-doped SnO₂), FTO (F-doped SnO₂), a zinc oxide (ZnO), an aluminum oxide-doped zinc oxide (AZO), a gallium-doped zinc oxide (GZO), B-doped ZnO, AlMgZnO (aluminum oxide and magnesium oxide-doped zinc oxide), an antimony oxide, a titanium oxide, NiO, a spinel type oxide, or an oxide having a YbFe₂O₄ structure. Furthermore, the first electrode 103 may have a structure in which a transparent conductive material having an excellent hole injection characteristic, such as an oxide of indium and tin (ITO) or an oxide of indium and zinc (IZO), is laminated on a multilayer film having a gallium oxide, a titanium oxide, a niobium oxide, a nickel oxide, or the like as a base layer or a reflective film having high light reflectivity, such as aluminum.

### (Organic Compound Layer)

The organic compound layer 102 is provided on the first electrode 103 and the insulating layer 108. The organic compound layer 102 includes at least a light emitting layer. The organic compound layer 102 is also provided on a part of the insulating layer 108.

The light emitting layer is formed of an organic light emitting material. In the light emitting layer, electrons and holes injected from the first electrode 103 and the second electrode 104 are coupled to generate light. In the display device 101a, the organic compound layer 102 having a light emitting layer using organic light emitting materials having emitted light colors corresponding to the types of the sub-pixels 106 is provided. In a case where two or more types of the sub-pixels 106 are provided, the organic compound layer 102 is provided for each type of the sub-pixels 106 in a pattern corresponding to the type of the sub-pixels 106.

In the display device 101a illustrated in the example of FIGS. 1A, 1B, and 2, the three types of sub-pixels 106R, 106G, and 106B having different emitted light colors are provided, and the organic compound layer 102 is provided for each emitted light color. An organic compound layer 102R that emits red light (wavelength: 620 nm to 750 nm) is provided for the sub-pixels 106R, an organic compound layer 102G that emits green light (wavelength: 495 nm to 570 nm) is provided for the sub-pixels 106G, and an organic compound layer 102B that emits blue light (wavelength: 450 nm to 495 nm) is provided for the sub-pixels 106B. In a case where the organic compound layer 102R, the organic compound layer 102G, and the organic compound layer 102B are not distinguished from one another, they are also collectively referred to as the organic compound layer 102. Note that although end surfaces extending in the Y direction of the organic compound layer 102R, the organic compound layer 102G, and the organic compound layer 102B are in contact with each other in FIG. 1A for convenience of description, the end surfaces of the organic compound layer 102R, the organic compound layer 102G, and the organic compound layer 102B are generally separated from each other, as illustrated in FIG. 2. The same applies to the second electrode 104 and the protective layer 114.

The organic compound layer 102 is provided on the first electrode 103 in a shape defined so as to close the opening 109 in plan view of the display device 101a, and is further patterned in substantially the same shape as the second electrode 104. In a case where the organic compound layer 102 is patterned in substantially the same shape as the second electrode 104, it is easy to avoid direct contact among the second electrode 104R, the second electrode 104G, and the second electrode 104B at a multi-level crossing portion 112, which will be described later, and a periphery thereof. In the present specification, a case where a plurality of objects is provided in substantially the same shape includes a case where the objects are provided in the same shape.

In a case where the organic compound layer 102 is formed in substantially the same shape as the second electrode 104, the organic compound layer 102 is patterned in a shape connected between the sub-pixels 106. Furthermore, the organic compound layer 102 has branches. Branch positions of the organic compound layer 102 are located immediately below branching portions 122 of the second electrode 104. In the examples of FIGS. 1A, 1B, and 2, the organic compound layer 102 is connected between the sub-pixels 106 so as to straddle the sub-pixels 106 in a plan view of the display device 101a, that is, the organic compound layer 102 forms a plurality of column portions extending in the Y direction so as to straddle adjacent unit sections of the sub-pixels 106. Adjacent column portions of the organic compound layer 102 are connected by bridge portions extending in the X direction. The branches of the organic compound layer 102 are provided at connection portions between the column portions and the bridge portions. The branches are arranged two-dimensionally similarly to the second electrode 104.

Since the organic compound layer 102 is provided in substantially the same shape as the second electrode 104, steps of patterning the organic compound layer 102 and the second electrode 104 can be merged. This can make it less likely that a processing liquid or the like used during the patterning affects performance of the organic compound layer 102.

In the example of FIGS. 1A, 1B, and 2, the organic compound layer 102R, the organic compound layer 102G, and the organic compound layer 102B are patterned in substantially the same shapes as the second electrode 104R, the second electrode 104G, and the second electrode 104B, respectively.

In a case where the first electrode 103 is an anode electrode and the second electrode 104 is a cathode electrode, the organic compound layer 102 may have a structure in which a hole transport layer, a light emitting layer, and an electron transport layer are laminated in this order from the first electrode 103 toward the second electrode 104 (from bottom to top). In a case where the organic compound layer 102 has such a structure, light emission efficiency can be further increased. Furthermore, the organic compound layer 102 may have a structure in which a hole injection layer, a hole transport layer, a light emitting layer, an electron transport layer, and an electron injection layer are laminated in this order from the first electrode 103 toward the second electrode 104.

The hole transport layer is a layer that enhances efficiency of hole transport to the light emitting layer. The hole injection layer is a layer that enhances efficiency of hole injection from the first electrode 103 to the hole transport layer. The electron injection layer is a layer that enhances efficiency of electron injection from the second electrode 104 to the electron transport layer. The electron transport layer is a layer that enhances efficiency of electron transport to the light emitting layer.

In a case where a plurality of types of sub-pixels 106 having different emitted light colors is provided, the organic compound layers 102 constituting the sub-pixels 106 may have different thicknesses. Therefore, the thicknesses of the organic compound layers 102 constituting the sub-pixels 106 may be set to appropriate thicknesses according to the emitted light colors. For example, different thicknesses may be determined as the thickness of the organic compound layer 102R, the thickness of the organic compound layer 102G, and the thickness of the organic compound layer 102B.

In a case where the organic compound layer 102 is provided in substantially the same shape as the second electrode 104, it is, for example, preferable that an end surface 102a of the organic compound layer 102 and an end surface 104a of the second electrode 104 form a continuous surface, as illustrated in the example of FIG. 1B. Note that in this case, the organic compound layer 102 and the second electrode 104 more preferably have a tapered shape, as illustrated in the example of FIG. 1B.

### (Second Electrode)

In the display device 101a, the second electrode 104 is provided on the organic compound layer 102. As described above, the second electrode 104 functions as an electrode that controls a light emission state of the sub-pixels 106 in combination with the first electrode 103.

The second electrode 104 is provided according to each type of the sub-pixels 106. That is, in a case where two or more types of sub-pixels 106 are provided, the second electrode 104 is provided according to each type of sub-pixels 106. In the example of FIGS. 1A, 1B, and 2, three types of second electrodes, that is, a second electrode 104R for red, a second electrode 104G for green, and a second electrode 104B for blue are provided corresponding to the sub-pixel 106R, the sub-pixel 106G, and the sub-pixel 106B, respectively. Note that, in the present specification, the second electrode 104R, the second electrode 104G, and the second electrode 104B may be collectively referred to as the second electrode 104 unless types such as color types are particularly distinguished.

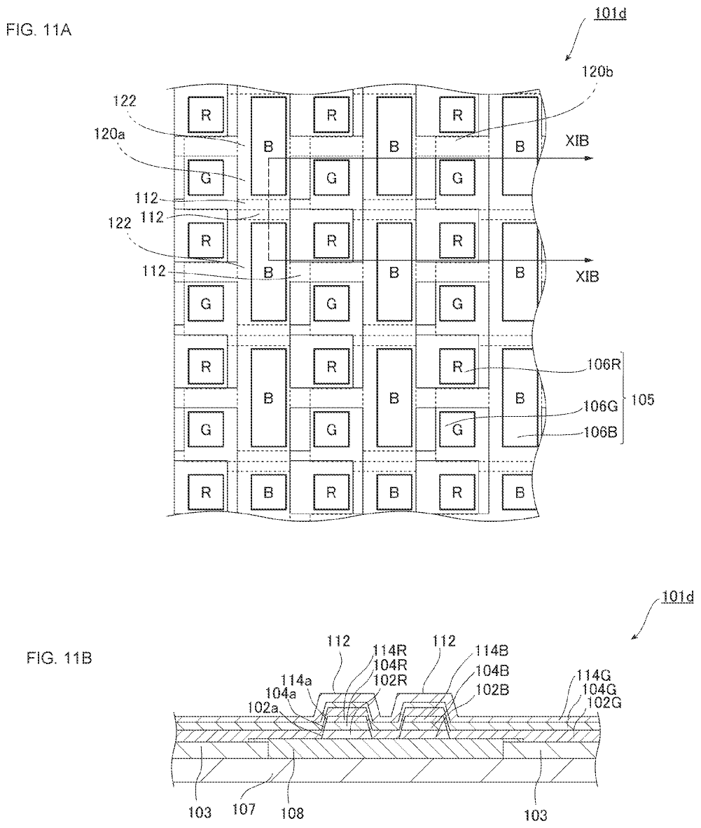

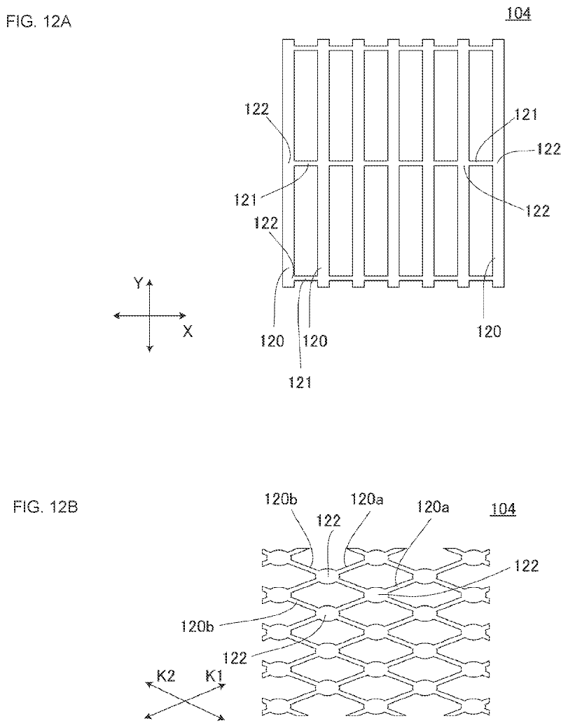

The second electrode 104 is patterned so as to straddle the sub-pixels 106 and be connected between the sub-pixels 106. Furthermore, the second electrode 104 has the plurality of branching portions 122 connected to each other. The branching portions 122 are arranged two-dimensionally and electrically connect portions of the second electrodes 104 corresponding to the unit sections of the sub-pixels 106. In the example of FIG. 1A, the second electrode 104 has column portions 120 continuous in the Y direction so as to straddle adjacent unit sections of the sub-pixels 106. As illustrated in FIG. 12A, adjacent column portions 120 of the second electrode 104 are connected by bridge portions 121 extending in the X direction. The second electrode 104 has the branching portions 122 at connection portions between the column portions 120 and the bridge portions 121, and portions of the second electrode 104 that form the branching portions 122 are arranged two-dimensionally (in a grid manner in the example of FIGS. 1A and 12A) in the X direction and the Y direction. Note that FIG. 12A illustrates an example of second electrode 104 of the display device 101a.

Furthermore, the second electrode 104 is preferably patterned in a mesh shape. In a case where the second electrode 104 is provided in a mesh-like pattern, it is easy to realize more uniform image display.

In the example of FIG. 1A, the second electrode 104 is patterned so as to be connected in the X direction and the Y direction and expand in a grid mesh shape as a whole, as also illustrated in FIG. 12A.

Moreover, each of the second electrode 104R, the second electrode 104G, and the second electrode 104B is patterned so as to be connected in a grid mesh shape in the X direction and the Y direction and connected as a whole.

### (Multi-Level Crossing Portion)

In a case where two or more types of sub-pixels 106 are provided, a portion of the second electrode 104 that forms the sub-pixel 106 of a predetermined type and a portion of the second electrode 104 that forms the sub-pixel 106 of a type different from the predetermined type are laminated so as to cross in multiple levels. This laminated portion forms the multi-level crossing portion 112.

In the example of FIGS. 1A and 1B, the multi-level crossing portion 112 is provided at a portion where the second electrode 104R and the second electrode 104G cross each other in plan view of the display device 101a. Furthermore, the multi-level crossing portion 112 in which the second electrode 104R and the second electrode 104G cross each other is provided.

Similarly, the multi-level crossing portion 112 is provided at a portion where the second electrode 104G and the second electrode 104B cross each other.

As long as the multi-level crossing portion 112 is provided so that direct contact is avoided between portions of the second electrode 104 that cross each other, upper and lower positions of the second electrode 104 that cross each other and a crossing direction are not particularly limited. For example, in a case where the second electrode 104R and the second electrode 104G cross each other, any one of the second electrode 104R and the second electrode 104G may be on an upper side. Note that, from a viewpoint of suppressing occurrence of a defect of the second electrode 104, the number of second electrodes 104 crossing each other is preferably 2 or less.

The multi-level crossing portion 112 is preferably provided so as to avoid the opening 109 of the insulating layer 108 in plan view of the display device 101a. In a case where the multi-level crossing portion 112 is provided so as to avoid the opening 109, a possibility that the light emission state of the sub-pixels 106 is affected by the multi-level crossing portion 112 can be made low with more certainty. In the example of FIG. 1A, the second electrode 104R is patterned so as to straddle a portion between adjacent openings 109 that form the sub-pixels 106G. Moreover, the second electrode 104R is patterned so as to straddle a portion between adjacent openings 109 that form the sub-pixels 106B. Similarly to the second electrode 104R, the second electrode 104G straddles a portion between adjacent openings 109 of the sub-pixels 106R and straddles a portion between adjacent openings 109 of the sub-pixels 106B. Similarly to the second electrode 104R, the second electrode 104B straddles a portion between adjacent openings 109 of the sub-pixels 106R and straddles a portion between adjacent openings 109 of the sub-pixels 106G.

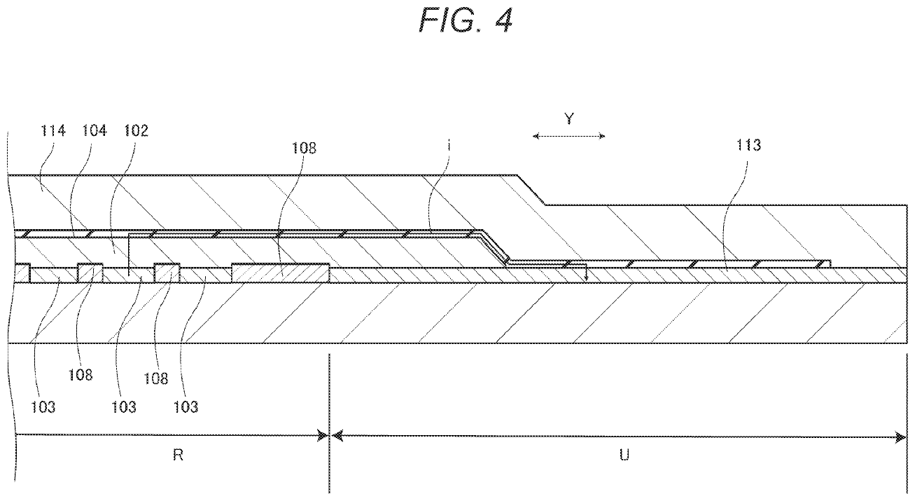

As illustrated in FIG. 4, the second electrode 104 preferably extends from the pixel region R to the non-pixel region U. In this case, in a case where the second electrode 104 is electrically connected to an external circuit, a connection portion between the second electrode 104 and the external circuit can be located in the non-pixel region U. Note that for convenience of description, description of the multi-level crossing portion 112 is omitted in FIG. 4.

Furthermore, in the display device 101a, an auxiliary electrode portion 113 is provided in the non-pixel region U. The auxiliary electrode portion 113 is provided in a shape surrounding an entire periphery or a part of the periphery of the pixel region R. The auxiliary electrode portion 113 may have, for example, a ring shape, a U shape, or the like in plan view of the display device 101a. The auxiliary electrode portion 113 can be made of a similar material to the first electrode 103.

In such a display device 101a, the second electrode 104 is preferably connected to the auxiliary electrode portion 113 provided in the non-pixel region U, as illustrated in FIG. 4. In this case, the second electrode 104 can be electrically connected to the external circuit with the auxiliary electrode portion 113 interposed therebetween, and a path of a current i passing from the first electrode toward the auxiliary electrode 13 through the second electrode can be formed.

In a case where the second electrode 104 is a cathode electrode, the second electrode 104 may be formed of a metal oxide. The metal oxide may be, for example, a transparent conductive material such as IZO, ITO, ZnO, SnO, AZO, or GZO.

Furthermore, the second electrode 104 may be for example, formed of aluminum (Al), silver (Ag), magnesium (Mg), calcium (Ca), sodium (Na), strontium (Sr), an alkali metal or an alkaline earth metal and silver, an alloy of magnesium and silver, an alloy of magnesium and calcium, an alloy of aluminum and lithium (Li), or the like.

### (Protective Layer)

The protective layer 114 is provided on the second electrode 104. The protective layer 114 is formed of an insulating material. As the insulating material, for example, a thermosetting resin or the like can be used. Alternatively, the insulating material may be SiN, SiO, SiON, AlO, TiO, or the like and these materials may be laminated. In this case, as the protective layer 114, a CVD film containing SiN, SiO, SiON, or the like, an ALD film containing AlO, TiO, SiO, or the like, or the like can be exemplified.

In the display device 101a, in a case where two or more types of the sub-pixels 106 are provided, the protective layer 114 is provided for each type of sub-pixels 106.

For example, in the display device 101a illustrated in FIGS. 1A, 1B, and 2 and other drawings, a protective layer 114R, a protective layer 114G, and a protective layer 114B are patterned corresponding to the three types of sub-pixels 106R, 106G, and 106B, respectively. In a case where the protective layer 114R, the protective layer 114G, and the protective layer 114B are not distinguished from one another, they are also collectively referred to as the protective layer 114.

The protective layer 114 is preferably patterned in substantially the same shape as the second electrode 104 in plan view of the display device 101a. In a case where the protective layer 114 is formed in substantially the same shape as the second electrode 104, the protective layer 114 is patterned so as to straddle the sub-pixels 106 and be connected between the sub-pixels 106. Furthermore, the protective layer 114 has branches. Branch positions of the protective layer 114 are located immediately above the branching portions 122 of the second electrode 104. In the example of FIGS. 1A, 1B, and 2 and other drawings, the protective layer 114 is connected between the sub-pixels 106 so as to straddle the sub-pixels 106 in a plan view of the display device 101a, that is, the protective layer 114 forms a plurality of column portions extending in the Y direction so as to straddle adjacent unit sections of the sub-pixels 106. Adjacent column portions of the protective layer 114 are connected by bridge portions extending in the X direction. The branches of the protective layer 114 are provided at connection portions between the column portions and the bridge portions. The branches are arranged two-dimensionally similarly to the second electrode 104.

It is more preferable that not only the protective layer 114 is provided in substantially the same shape as the second electrode 104, but also the protective layer 114 and the organic compound layer 102 are provided in substantially the same shape. In this case, steps of patterning the protective layer 114, the second electrode 104, and the organic compound layer 102 can be merged. This can make it less likely that a processing liquid or the like used during the patterning affects performance of the organic compound layer 102.

In the example of FIGS. 1A, 1B, and 2 and other drawings, the protective layer 114R, the second electrode 104R, and the organic compound layer 102R are patterned in substantially the same shape. The protective layer 114G, the second electrode 104G, and the organic compound layer 102G are patterned in substantially the same shape. Furthermore, the protective layer 114B, the second electrode 104B, and the organic compound layer 102B are patterned in substantially the same shape.

In a case where the protective layer 114, the second electrode 104, and the organic compound layer 102 are provided in substantially the same shape, it is, for example, preferable that an end surface 114a of the protective layer 114, the end surface 102a of the organic compound layer 102, and the end surface 104a of the second electrode 104 form a continuous surface, as illustrated in the example of FIGS. 1A and 1B.

Furthermore, in a case where the continuous surface is formed, the protective layer 114, the second electrode 104, and the organic compound layer 102 preferably have a tapered shape. In a case where the end surface 114a of the protective layer 114, the end surface 104a of the second electrode 104, and the end surface 102a of the organic compound layer 102 form a continuous surface, it is possible to reduce a possibility that a defect of the second electrode 104 located on an upper side at the multi-level crossing portion 112 occurs at and in the vicinity of the multi-level crossing portion 112. Furthermore, in a case where the protective layer 114, the second electrode 104, and the organic compound layer 102 have a tapered shape, it is possible to more effectively suppress a defect at and in the vicinity of the multi-level crossing portion 112.

The protective layer 114 covers an uppermost surface of the laminated structure of the organic compound layer 102 and the second electrode 104. By providing the protective layer 114, it is possible to restrict mutual contact of an upper surface side of the laminated structure of the organic compound layer 102 and the second electrode 104 at the multi-level crossing portion 112. In the example of FIG. 1B, for example, contact of the laminated structure of the organic compound layer 102G and the second electrode 104G and the laminated structure of the organic compound layer 102B and the second electrode 104B with the upper surface of the laminated structure of the organic compound layer 102R and the second electrode 104R is avoided.

### (Filling Layer)

In the display device 101a, a filling layer 115 is provided on the protective layer 114.

In the example of FIG. 2, the filling layer 115 is provided so as to cover all of the protective layer 114G, the protective layer 114B, and the protective layer 114R.

Since the filling layer 115 is provided in the display device 101a, a surface where the protective layer 114 is formed can be planarized in the display device 101a. Furthermore, entry of moisture or the like into the organic compound layer 102 from the outside can be effectively avoided. The filling layer 115 may be, for example, a layer formed of a similar resin to the protective layer 114, a layer formed of an organic resin, or a laminate thereof. As the case where the filling layer 115 is a laminate, a laminate of a layer (referred to as a barrier layer) formed of a similar resin to the protective layer 114 and a layer formed of a resin for adhesion on the barrier layer can be exemplified. Examples of the organic resin include a resin forming a layer for planarization, and specific examples thereof include known materials such as a thermosetting resin and an ultraviolet curable resin.

### (Color Filter)

On the filling layer 115, a color filter 116 is disposed at positions corresponding to the sub-pixels 106. In the display device 101a, in a case where two or more types of sub-pixels 106 are provided, the color filter 116 is provided for each type of sub-pixel 106.

In the example of FIG. 2, on the filling layer 115, a red color filter 116R is disposed at a position corresponding to the sub-pixels 106R, a green color filter 116G is disposed at a position corresponding to the sub-pixels 106G, and a blue color filter 116B is disposed at a position corresponding to the sub-pixels 106B. Note that, in the present specification, the red color filter 116R, the green color filter 116G, and the blue color filter 116B may be collectively referred to as the color filter 116 when they are not distinguished from one another.

The red color filter 116R, the green color filter 116G, and the blue color filter 116B adjust colors or wavelengths of light emitted from the organic compound layer 102R, the organic compound layer 102G, and the organic compound layer 102B, respectively. The red color filter 116R, the green color filter 116G, and the blue color filter 116B need not be provided in some cases.

### (Black Matrix)

A black matrix layer 117 is provided between adjacent color filters 116. The black matrix layer 117 can prevent light emitted from the organic compound layer 102 from entering the color filter 116 of adjacent another sub-pixel 106, thereby preventing color mixing.

The black matrix layer 117 may be, for example, a black resin film mixed with a black colorant and having an optical density of 1 or more. Specifically, a black polyimide resin or the like can be exemplified as a material of the black matrix layer 117. Note that the black matrix layer 117 need not necessarily be provided.

### (Counter Glass or the Like)

A lens and the like (not illustrated) are disposed on a layer where the color filter 116 and the black matrix layer 117 are provided, a sealing layer 119 and the like is further provided, and counter glass 118 is provided on the sealing layer 119. The sealing layer 119 can be formed of a resin or the like. Due to the presence of the sealing layer 119, entry of moisture or the like into the organic compound layer 102 from the outside can be effectively avoided. As the sealing layer 115, for example, a layer formed of an organic resin or the like may be adopted, and known materials such as a thermosetting resin and an ultraviolet curable resin can be exemplified. The counter glass 118 is only required to be formed of a material that allows light emitted from the organic compound layer 102 to pass therethrough. Examples of the counter glass 118 include various glass substrates such as high strain point glass, soda glass, borosilicate glass, and lead glass, and quartz substrates. Note that the lens may be provided below the layer in which the color filter 116 is provided.

### (Effects)

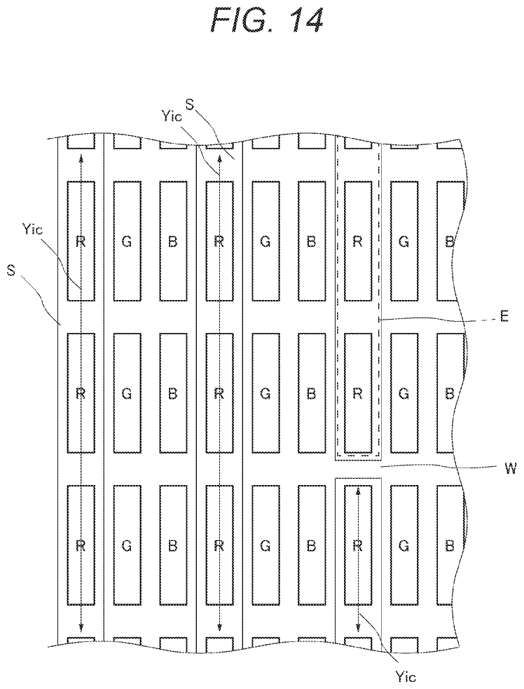

In a conventional display device having a stripe-shaped second electrode S, for example, in a case where a defect such as disconnection occurs at a position W of the stripe-shaped second electrode S for red sub-pixels as illustrated in FIG. 14, there is a possibility that a current does not flow in a portion E of the second electrode S (a portion surrounded by the broken line in FIG. 14) even if a current in a Yic direction flows in other parts of the portion E of the second electrode S. Therefore, there is a possibility that energization in the portion E is cut off. In the display device 101a, even in a case where a defect such as disconnection occurs at a position W of the second electrode 104 (104R) for the red sub-pixels 106R, a current flowing in a Yi direction in the column portion 120 different from the column portion 120 corresponding to the position W flows in the Xi direction in the bridge portion 121 via the branching portion 122, as illustrated in FIG. 3. Accordingly, energization in the Yi direction can be performed also in the portion E, and an energized state of the sub-pixel 106 in the portion E (the portion surrounded by the broken line in FIG. 3) can be easily maintained. Therefore, it is possible to suppress occurrence of a line defect in an image displayed on the display device 101a. FIG. 3 illustrates an example of a state of the second electrode 104 in a case where the second electrode 104 of the display device 101a has a defect. FIG. 14 illustrates an example of a state of the second electrode S in a case where the second electrode S of the conventional display device has a defect. Furthermore, in FIG. 3, arrows Yi and Xi indicate directions in which a current can flow in the second electrode 104 of the display device 101a. In FIG. 14, an arrow Yic indicates a direction in which a current can flow in the second electrode S.

Furthermore, according to the second electrode 104 of the display device 101a, a current can flow not only in the Y direction but also in the X direction, and therefore the number of paths through which a current flows in the second electrode 104 increases. Therefore, influence of a variation in wiring resistance can be suppressed, and for example, a luminance variation of the display device 101a can be suppressed. This can be more effectively realized in a case where the second electrode 104 is patterned in a mesh shape.

When the display device 101a is manufactured, a resist matching the pattern shape of the second electrode 104 is provided as a resist for patterning the organic compound layer 102, the second electrode 104, and the protective layer 114. In a case where the second electrode 104 of the display device 101a is provided in a mesh shape, the resist also has a mesh shape. As a result, resist collapse is less likely to occur even when a high-definition pattern is formed, and a possibility of occurrence of a defect during pattern formation can be reduced.

### [2. Method of Manufacturing Display Device]

Hereinafter, a method of manufacturing the display device 101a illustrated in FIGS. 1A, 1B, and 2 and other drawings will be described in detail as an example.

### (Step of Forming First Electrode and Insulating Layer)

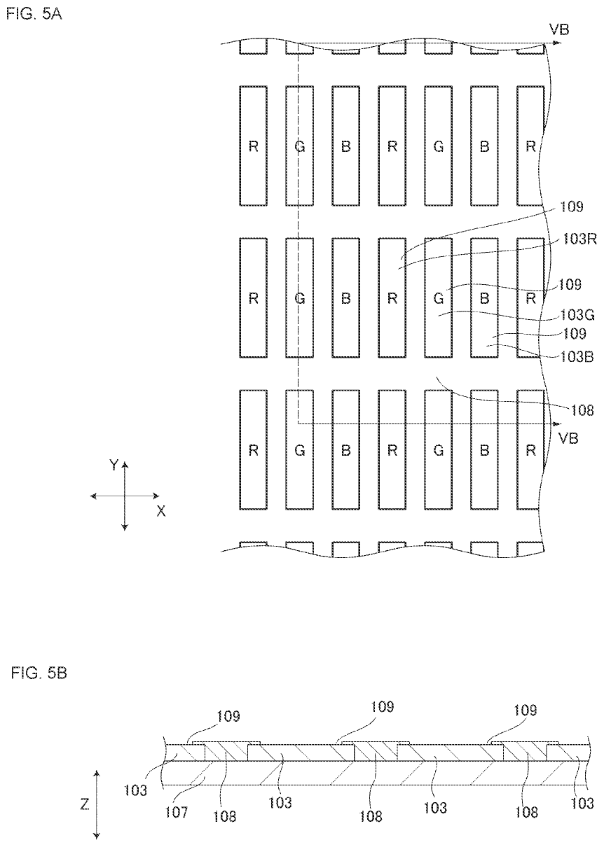

As illustrated in FIGS. 5A and 5B, the first electrode 103 is formed on the substrate 107 including a drive circuit such as a drive transistor that drives the display device 101a, and the insulating layer 108 is further laminated. The opening 109 is formed in the insulating layer 108 in accordance with the pattern of the sub-pixels 106. The first electrode 103 and the insulating layer 108 can be, for example, formed by a sputtering method, chemical vapor deposition (CVD), atomic layer deposition (ALD), or the like.

Specifically, for example, a metal layer made of ITO is formed as the first electrode 103 on the substrate 107 in which a circuit layer including the drive circuit is formed on a Si substrate, and the metal layer is patterned by using a photolithography technique and an etching technique. In this process, the first electrode 103 is formed in such an arrangement pattern that the first electrode 103 is separated two-dimensionally in a manner corresponding to the unit sections of the sub-pixels 106. In the example of FIGS. 5A and 5B, the first electrodes 103 (103R, 103G, and 103B) are formed at positions corresponding to the three types of sub-pixels 106 (106R, 106G, and 106B).

The insulating layer 108 is formed on a surface of the substrate 107 on which the first electrode 103 is formed, and the opening 109 is patterned in accordance with the pattern of the sub-pixels 106. In this process, the insulating layer 108 is formed so as to fill a region between the opening 109 and the patterned metal layer. Specifically, the insulating layer 108 may be formed of SiON or the like.

(Step of Forming Laminated Structure in which Protective Layer 114R, Second Electrode 104R, and Organic Compound Layer 102R are Laminated)

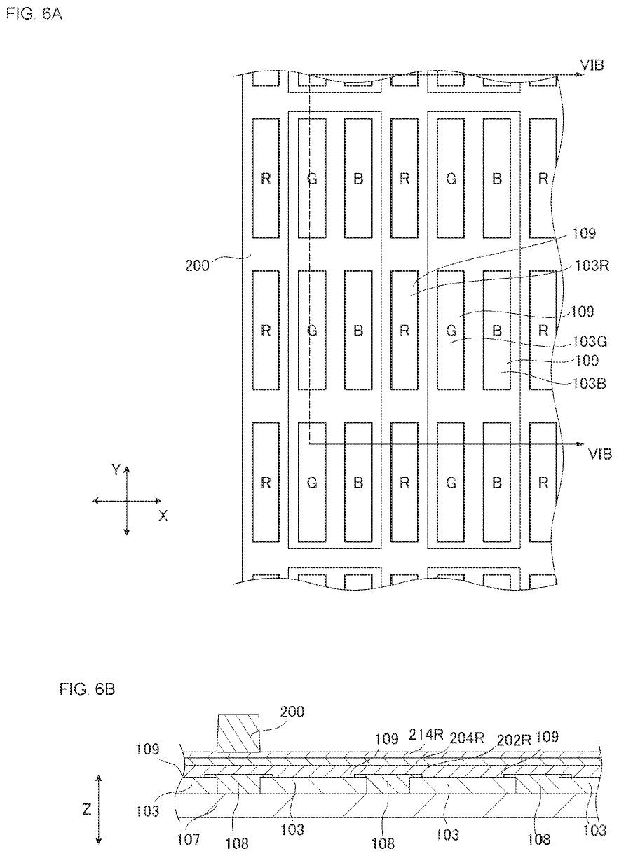

As illustrated in FIGS. 6A and 6B, a layer 202R forming the organic compound layer 102R corresponding to the sub-pixel 106R, a layer 204R forming the second electrode 104R, and a layer 214R forming the protective layer 114R are formed in this order on the first electrode 103 and the insulating layer 108. Examples of a method for forming these layers include a vacuum vapor deposition method, sputtering, chemical vapor deposition (CVD), and atomic layer deposition (ALD), and further include coating methods such as a spin coating method and a die coating method.

A configuration of the layer 202R forming the organic compound layer 102R is determined corresponding to a layer configuration of the organic compound layer 102R in the display device 101a. For example, in a case where the organic compound layer 102R has a structure in which an electron transport layer, a light emitting layer, and a hole transport layer are laminated in this order, the layer 202R forming the organic compound layer 102R is only required to have a structure in which layers forming an electron transport layer, a light emitting layer, and a hole transport layer are laminated.

In a case where the second electrode 104R is made of IZO, for example, it is only necessary that an IZO film is formed as the layer 204 R forming the second electrode 104R. Examples of the layer 214R forming the protective layer 114R include a CVD film containing SiN, SiO, SiON, or the like.

A resist 200 is formed on the layer 214R forming the protective layer 114R. The resist 200 is formed in a pattern corresponding to the shape of the second electrode 104R. The resist 200 is formed on a surface of a laminated body in which the layer 202R forming the organic compound layer 102R, the layer 204R forming the second electrode 104R, and the layer 214R forming the protective layer 114R, and a photolithography method, a dry etching method, or the like is applied while using the resist 200 as a mask. In this way, a laminated structure in which the protective layer 114R, the second electrode 104R, and the organic compound layer 102R are laminated is formed on the first electrode 103R. The protective layer 114R and the organic compound layer 102R are formed in substantially the same shape as the shape of the second electrode 104R.

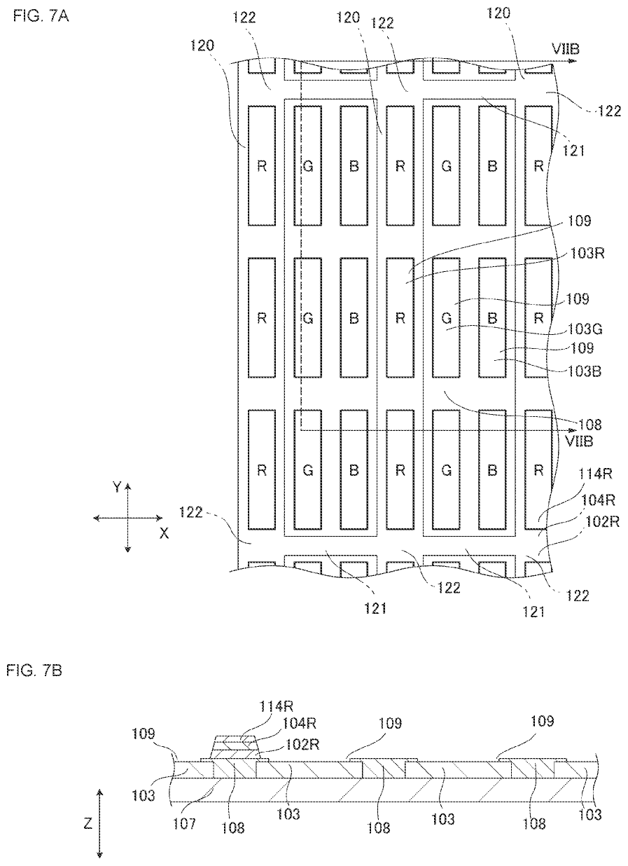

As illustrated in FIGS. 7A and 7B, after the laminated structure in which the protective layer 114R, the second electrode 104R, and the organic compound layer 102R are laminated is formed, the resist 200 formed on the protective layer 114R is removed. To remove the resist 200, a method such as a method using asking, a removal liquid, or the like can be used.

(Step of Forming Laminated Structure in which Protective Layer 114G, Second Electrode 104G, and Organic Compound Layer 102G are Laminated)

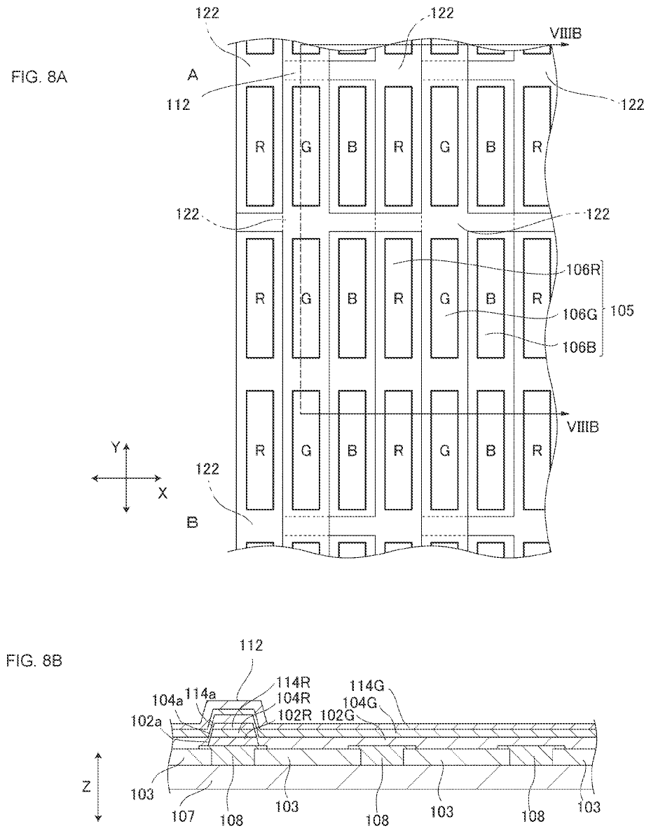

Next, a step of forming a laminated structure in which the protective layer 114G, the second electrode 104G, and the organic compound layer 102G are laminated is performed by a similar method to the step of forming the laminated structure in which the protective layer 114R, the second electrode 104R, and the organic compound layer 102R are laminated. Note that a resist corresponding to the shape of the second electrode 104G is used instead of the resist 200 corresponding to the shape of the second electrode 104R. In this way, a laminated structure in which the protective layer 114G, the second electrode 104G, and the organic compound layer 102G are laminated is formed, as illustrated in FIGS. 8A and 8B. In FIG. 8A, for convenience of description, description of the protective layer 114R and the organic compound layer 102R, and the protective layer 114G and the organic compound layer 102G is omitted.

(Step of Forming Laminated Structure in which Protective Layer 114B, Second Electrode 104B, and Organic Compound Layer 102B are Laminated)

Next, after the laminated structure in which the protective layer 114G, the second electrode 104G, and the organic compound layer 102G are laminated is formed, a step of forming a laminated structure in which the protective layer 114B, the second electrode 104B, and the organic compound layer 102B are laminated is performed by a similar method to the step of forming the laminated structure in which the protective layer 114R, the second electrode 104R, and the organic compound layer 102R are laminated. Note that a resist corresponding to the shape of the second electrode 104B is used instead of the resist 200 corresponding to the shape of the second electrode 104R. In this way, the laminated structure in which the protective layer 114R, the second electrode 104R, and the organic compound layer 102R are laminated, the laminated structure in which the protective layer 114G, the second electrode 104G, and the organic compound layer 102G are laminated, and the laminated structure in which the protective layer 114B, the second electrode 104B, and the organic compound layer 102B are laminated are formed as illustrated in FIGS. 1A and 1B.

Note that an order of the step of forming the laminated structure in which the protective layer 114R, the second electrode 104R, and the organic compound layer 102R are laminated, the step of forming the laminated structure in which the protective layer 114G, the second electrode 104G, and the organic compound layer 102G are laminated, and the step of forming the laminated structure in which the protective layer 114B, the second electrode 104B, and the organic compound layer 102B are laminated is not limited to the above order.

### (Step of Forming Filling Layer)

The filling layer 115 is formed so as to cover all of the protective layer 114R, the protective layer 114G, and the protective layer 114B. For example, the filling layer 115 can be obtained by forming a layer formed of a similar resin to the protective layer 114 and further forming a layer formed of a resin for adhesion or the like thereon.

Then, a laminated component in which the sealing layer 119, the lens (not illustrated), the color filter 116, and the black matrix layer 117 are arranged on the counter glass 118 is disposed and fixed on the filling layer 115 so that a side where the color filter 116 is disposed faces the filling layer 115 side. In this way, the display device 101a is formed. Note that in this case, the black matrix layer 117 and the sealing layer 119 may be omitted.

### (Modification of Method of Manufacturing Display Device)

Although the laminated component in which the color filter 116, the black matrix layer 117, and the like are formed is disposed on the filling layer 115 in the method of manufacturing the display device described above, the method of manufacturing the display device is not limited to this. In the method of manufacturing the display device, layers such as the color filter 116 and the black matrix layer 117 may be sequentially formed on the filling layer 115.

In this case, as for the steps up to the step of forming the filling layer, the steps described in the above method of manufacturing the display device are performed. However, the filling layer 115 formed in the step of forming the filling layer need not have a layer formed of an adhesive resin or the like. For example, as the filling layer 115, a layer formed of a similar resin to the protective layer 114, a layer formed of an organic resin, or the like may be adopted. As the organic resin, a resin forming a layer for planarization can be exemplified, as already described.

After the step of forming the filling layer, the color filter 116 and the black matrix layer 117 are formed on the filling layer 115. The lens is disposed on the color filter 116. Then, a resin forming the sealing layer 119 is applied all over a surface so as to cover the surface on which the lens is disposed. Further, the counter glass 118 is disposed on the resin surface thus applied all over the surface, and the counter glass 118 is fixed by solidification of the sealing layer 119. In this way, the display device 101a is formed. Note that also in this case, the black matrix layer 117 need not necessarily be provided, as described above.

Furthermore, as the resin forming the sealing layer 119, for example, an ultraviolet curable resin, a thermosetting resin, or the like can be used.

### (Effects)

According to the above manufacturing method, the protective layer 114, the second electrode 104, and the organic compound layer 102 are formed by a photolithography method, a dry etching method, or the like while using a resist as a mask after a layer forming the organic compound layer 102, a layer forming the second electrode 104, and a layer forming the protective layer 114 are laminated. Therefore, the end surface 102a of the organic compound layer 102, the end surface 104a of the second electrode 104, and the end surface 114a of the protective layer 114 can be made continuous surfaces. Since the end surface 102a of the organic compound layer 102, the end surface 104a of the second electrode 104, and the end surface 114a of the protective layer 114 are continuous surfaces (flush), it is possible to reduce a possibility of occurrence of a defect in the second electrode 104 at and in the vicinity of the multi-level crossing portion 112 during manufacturing of the display device 101a.

In a case where the display device 101a is manufactured by the above manufacturing method, the end surface 102a of the organic compound layer 102, the end surface 104a of the second electrode 104, and the end surface 114a of the protective layer 114 are continuous surfaces, and the organic compound layer 102, the second electrode 104, and the protective layer 114 can be formed in a tapered shape. In the case of manufacturing the display device 101a, the organic compound layer 102, the second electrode 104, and the protective layer 114 are formed in a tapered shape, and the end surfaces 102a, 104a, and 114a form a continuous surface, as described above. This produces the following effects.

Specifically, it is possible to reduce a possibility that a defect of the second electrode 104 located on an upper side at the multi-level crossing portion 112 occurs at and in the vicinity of the multi-level crossing portion 112 during manufacturing of the display device 101a.

For example, in the multi-level crossing portion 112 in which the second electrode 104R is located on a lower side and the second electrode 104G is located on an upper side, the laminated structure in which the organic compound layer 102G, the second electrode 104G, and the protective layer 114G are laminated rides on the laminated structure in which the organic compound layer 102R, the second electrode 104R, and the protective layer 114R are laminated, as illustrated in FIGS. 8A and 8B and other drawings. In this state, in a case where the organic compound layer 102R, the second electrode 104R, and the protective layer 114R are formed in a tapered shape and the end surfaces 102a, 104a, and 114a thereof form a continuous surface, an end surface of the laminated structure in which the organic compound layer 102R, the second electrode 104R, and the protective layer 114R are laminated becomes a smooth inclined surface. This allows the laminated structure in which the organic compound layer 102G, the second electrode 104G, and the protective layer 114G are laminated can smoothly ride on the laminated structure in which the organic compound layer 102R, the second electrode 104R, and the protective layer 114R are laminated, thereby reducing a possibility of occurrence of a defect in the second electrode 104G.

### [3. Modification of Display Device]

In the above display device 101a, an example in which the arrangement pattern of the sub-pixels 106 is a stripe shape has been described. The arrangement pattern of the sub-pixels 106 is not limited to this. For example, the arrangement pattern of the sub-pixels 106 may be any of a matrix shape, a delta shape, and a combination of a stripe shape and a matrix shape.

### (Modification 1)

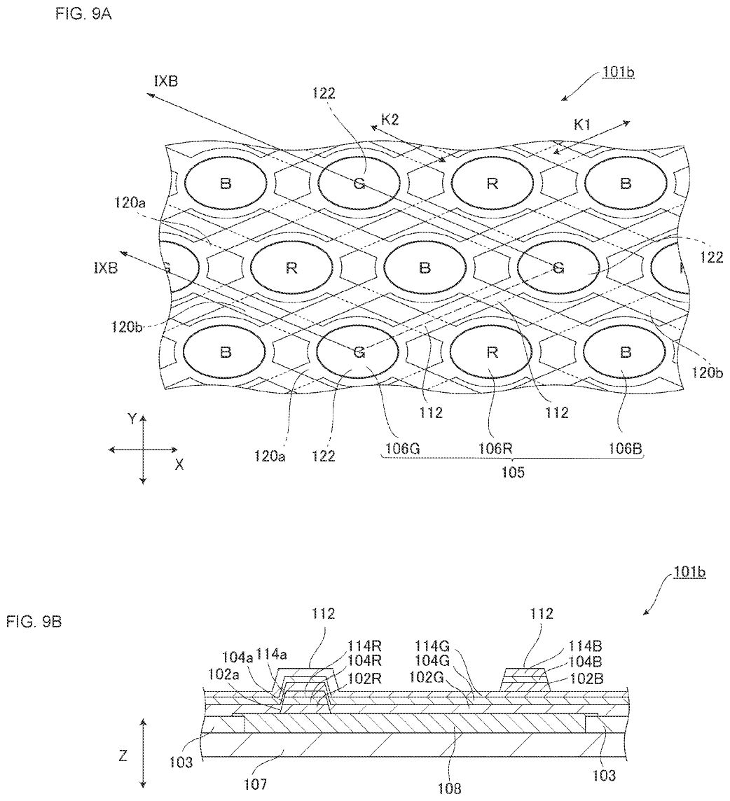

In a display device 101b illustrated in the example of FIGS. 9A and 9B, three types of sub-pixels 106, that is, red sub-pixels 106R, blue sub-pixels 106G, and green sub-pixels 106B are used as the sub-pixels 106, and the arrangement pattern of the sub-pixels 106 is a delta shape. That is, a shape obtained by connecting combinations of three sections (unit sections of the sub-pixels 106) of the sub-pixels 106R is an acute-angled triangle (delta shape), and combinations of three unit sections forming the acute-angled triangle are two-dimensionally arranged. Note that the unit sections are separated from each other. The same applies to the sub-pixels 106G and the sub-pixels 106B, and the three types of the sub-pixels 106R, 106G, and 106B are alternately arranged at positions shifted in a predetermined direction (X direction in FIG. 9A). Furthermore, combinations of the three types of sub-pixels 106R, 106G, and 106B arranged in the X direction are arranged side by side in a K1 direction diagonally crossing the X direction. Furthermore, the combinations of the three types of sub-pixels 106 are also arranged side by side in a K2 direction diagonally crossing the X direction.

In Modification 1, the second electrode 104 is patterned so as to straddle the sub-pixels 106 and be connected between the sub-pixels 106. Furthermore, the second electrode 104 has a plurality of branching portions 122 connected to each other, as also illustrated in FIG. 12B. Furthermore, the branching portions 122 are arranged two-dimensionally. As illustrated in FIG. 12B, the second electrode 104 forms column portions 120a and 120b continuous in the K1 direction and the K2 direction so as to straddle adjacent unit sections of the sub-pixels 106, and the branching portions 122 are provided at the positions of the sub-pixels 106. The organic compound layer 102 and the protective layer 114 are also patterned in a similar shape to the second electrode 104. Note that FIG. 12B illustrates an example of the second electrode 104 in Modification 1.

In Modification 1, a shape of the unit sections of the sub-pixels 106 is an elliptical shape in the example of FIG. 9A, but the shape of the unit sections of the sub-pixels 106 is not limited to this, and may be a polygon such as a hexagon, a triangle, a rectangle, a perfect circle, or the like.

### (Modification 2)

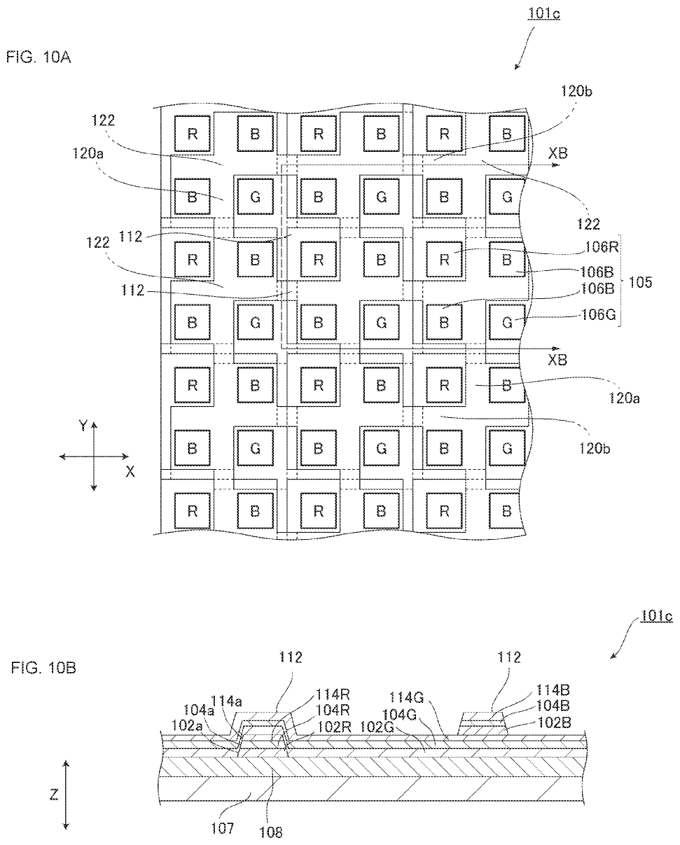

In a display device 101c illustrated in the example of FIGS. 10A and 10B, three types of sub-pixels 106, that is, red sub-pixels 106R, blue sub-pixels 106G, and green sub-pixels 106B are used as the sub-pixels 106, and the arrangement pattern of the sub-pixels 106 is a matrix shape. That is, the unit sections of the sub-pixels 106R are arranged in a matrix. The same applies to the sub-pixel 106G. In the example of FIGS. 10A and 10B, the sub-pixels 106B are arranged in a matrix for each of two unit sections arranged obliquely. In a unit section of a pixel 105, one unit section of the sub-pixel 106R, one unit section of the sub-pixel 106G, and two unit sections of the sub-pixel 106B obliquely arranged are disposed.

Although a shape of the unit sections of the sub-pixels 106 is a square in the example of FIG. 10A, the shape of the unit sections of the sub-pixels 106 is not limited to this.

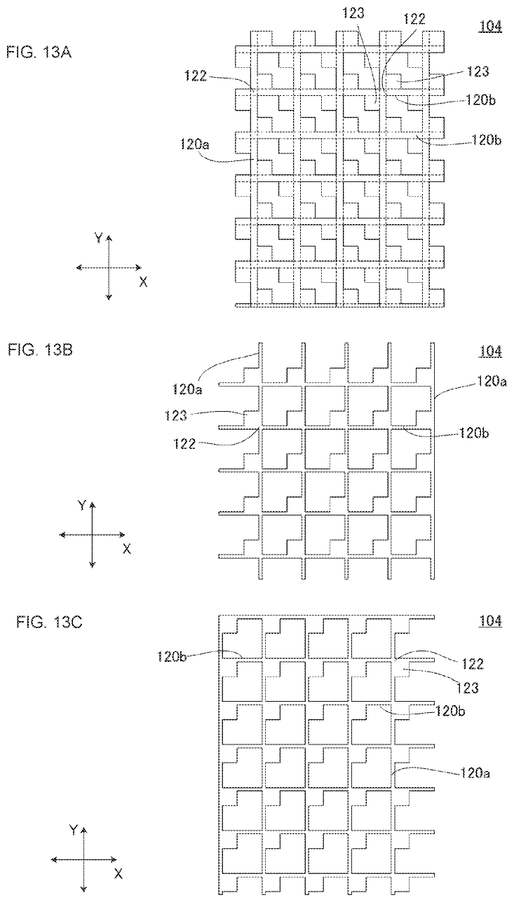

Also in Modification 2, the second electrode 104 is patterned so as to straddle the sub-pixels 106 and be connected between the sub-pixels 106. Furthermore, the second electrode 104 has a plurality of branching portions 122 connected to each other, as illustrated in FIGS. 13A to 13C. The branching portions 122 of the second electrode 104 are arranged two-dimensionally. In the example of FIG. 10A, the second electrode 104 has column portions 120a and 120b extending in the Y direction and the X direction as illustrated in FIGS. 13A to 13C, and the branching portions 122 are provided at intersections of the column portion 120a and the column portion 120b. FIG. 13A illustrates an example of the second electrode 104 (104B) for the sub-pixels 106B, FIG. 13B illustrates an example of the second electrode 104 (104G) for the sub-pixels 106G, and FIG. 13C illustrates an example of the second electrode 104 (104R) for the sub-pixels 106R. An extension portion 123 extends two-dimensionally from the branching portions 122 of the second electrode 104 so as to straddle the sub-pixels 106. In FIG. 13A, a state in which two extension portions 123 are provided so as to extend from one branching portion 122 is formed. In FIGS. 13B and 13C, one extension portion 123 is provided so as to extend from one branching portion 122. The organic compound layer 102 and the protective layer 114 are also patterned in a similar shape to the second electrode 104.

### (Modification 3)

In a display device 101d illustrated in the example of FIGS. 11A and 11B, three types of sub-pixels 106, that is, sub-pixels 106R, sub-pixels 106G, and sub-pixels 106B are used as the sub-pixels 106, and an arrangement pattern of the sub-pixels 106 is a combination of a stripe shape and a matrix shape. That is, unit sections of the sub-pixels 106R and the sub-pixels 106G are arranged in a matrix. Unit sections of the sub-pixels 106B are arranged in a stripe shape.

Also in Modification 3, the second electrode 104 is patterned so as to straddles the sub-pixels 106 and be connected between the sub-pixels 106. Furthermore, the second electrode 104 has the plurality of branching portions 122 connected to each other. In the example of FIG. 11A, the second electrode 104 (104R, 104G) can be provided as illustrated in FIGS. 13B and 13C as in Modification 2. The second electrode 104 (104B) can be provided in a similar manner to FIG. 12A. The organic compound layer 102 and the protective layer 114 are also patterned in a similar shape to the second electrode 104.

Similar effects to those of the display device 101a can be obtained for any of the display devices 101b, 101c, and 101d of Modifications 1 to 3. For example, it is possible to avoid occurrence of cutoff of energization in the sub-pixels 106 due to a defect of the second electrode 104, and it is possible to suppress occurrence of a line defect of an image displayed on the display devices 101b, 101c, and 101d.

Although examples of the display device, the manufacturing method, and the modifications of the present disclosure have been specifically described above, the present disclosure is not limited to the examples of the display device, the manufacturing method, and the modifications described above, and various modifications based on the technical idea of the present disclosure can be made.

For example, the configurations, methods, steps, shapes, materials, numerical values, and the like exemplified in the above examples of the display device, the manufacturing method, and the modifications are merely examples, and configurations, methods, steps, shapes, materials, numerical values, and the like different therefrom may be used as necessary.

Furthermore, the configurations, methods, steps, shapes, materials, numerical values, and the like exemplified in the above examples of the display device, the manufacturing method, and the modifications can be combined with each other without departing from the gist of the present disclosure.

The materials exemplified in the above display device, manufacturing method, and modifications can be used alone or in combination of two or more unless otherwise specified.

Note that the contents of the present disclosure are not to be construed as being limited by the effects exemplified in the present disclosure.

The present disclosure can also adopt the following configurations.

(1) A display device in which sub-pixels each having a structure in which a first electrode and a second electrode are laminated with an organic compound layer having a light emitting layer interposed therebetween are provided in such an arrangement pattern that the sub-pixels are two-dimensionally separated from each other, and

the second electrode is patterned so as to straddle the sub-pixels and be connected between the sub-pixels, and includes a plurality of branching portions connected to each other, and the branching portions are two-dimensionally arranged.

(2) The display device according to (1),

in which the second electrode is patterned in a mesh shape.

(3) The display device according to (1) or (2),

in which a pixel region and a non-pixel region are provided,

the sub-pixels are provided in the pixel region, and

the second electrode extends from the pixel region to the non-pixel region.

(4) The display device according to (3),

in which an auxiliary electrode portion is provided in the non-pixel region, and

the second electrode is connected to the auxiliary electrode portion.

(5) The display device according to any one of (1) to (4),

in which two or more types of sub-pixels are provided as the sub-pixels, and

the organic compound layer according to each type of the sub-pixels is patterned.

(6) The display device according to (5),

in which the types of the sub-pixels are based on a difference in emitted light color.

(7) The display device according to any one of (1) to (6),

in which two or more types of sub-pixels are provided as the sub-pixels, and

the second electrode according to each type of the sub-pixels is patterned.

(8) The display device according to (7),

in which a multi-level crossing portion where a part of the second electrode that forms the sub-pixels of a predetermined type and a part of the second electrode that forms the sub-pixels of a type different from the predetermined type cross each other is provided.

(9) The display device according to (8),

in which an insulating layer having an opening provided n a pattern according to the arrangement pattern of the sub-pixels is provided, and

the multi-level crossing portion is located so as to avoid the opening.

(10) The display device according to any one of (1) to (9),

in which the first electrode is an anode electrode, and

the second electrode is a cathode electrode.

(11) The display device according to any one of (1) to (10),

in which the arrangement pattern of the sub-pixels is selected from a group consisting of a stripe shape, a matrix shape, a delta shape, and a combination of the stripe shape and the matrix shape.

(12) The display device according to any one of (1) to (4), (10), and (11),

in which an end surface of the second electrode and an end surface of the organic compound layer form a continuous surface.

(13) The display device according to any one of (1) to (12),

in which two or more types of sub-pixels are provided as the sub-pixels, and

an end surface of the second electrode and an end surface of the organic compound layer form a continuous surface for each type of the sub-pixels.

### REFERENCE SIGNS LIST

101a, 101b, 101c, 101d Display device
102, 102R, 102G, 102B Organic compound layer
102a End surface of organic compound layer
103, 103R, 103G, 103B First electrode
104, 104R, 104G, 104B Second electrode
104a End surface of second electrode
105 Pixel
106, 106R, 106G, 106B Sub-pixel
107 Substrate
108 Insulating layer
109 Opening
112 Multi-level crossing portion
113 Auxiliary electrode portion
114, 114R, 114G, 114B Protective layer
115 Filling layer
116, 116R, 116G, 116B Color filter
117 Black matrix
118 Counter glass
119 Sealing layer
120, 120a, 120b Column portion
121 Bridge portion
122 Branching portion

1. A display device,
wherein sub-pixels each having a structure in which a first electrode and a second electrode are laminated with an organic compound layer having a light emitting layer interposed therebetween are provided in such an arrangement pattern that the sub-pixels are separated from each other,
the second electrode is patterned so as to straddle the sub-pixels and be connected between the sub-pixels, and includes a plurality of branching portions connected to each other, and the branching portions are two-dimensionally arranged.

2. The display device according to claim 1,
wherein the second electrode is patterned in a mesh shape.

3. The display device according to claim 1,
wherein a pixel region and a non-pixel region are provided,
the sub-pixels are provided in the pixel region, and
the second electrode extends from the pixel region to the non-pixel region.

4. The display device according to claim 3,
wherein an auxiliary electrode portion is provided in the non-pixel region, and
the second electrode is connected to the auxiliary electrode portion.

5. The display device according to claim 1,
wherein two or more types of sub-pixels are provided as the sub-pixels, and
the organic compound layer according to each type of the sub-pixels is patterned.

6. The display device according to claim 5,
wherein the types of the sub-pixels are based on a difference in emitted light color.

7. The display device according to claim 1,
wherein two or more types of sub-pixels are provided as the sub-pixels, and
the second electrode according to each type of the sub-pixels is patterned.

8. The display device according to claim 7,
wherein a multi-level crossing portion where a part of the second electrode that forms the sub-pixels of a predetermined type and a part of the second electrode that forms the sub-pixels of a type different from the predetermined type cross each other is provided.

9. The display device according to claim 8,
wherein an insulating layer having an opening provided n a pattern according to the arrangement pattern of the sub-pixels is provided, and
the multi-level crossing portion is located so as to avoid the opening.

10. The display device according to claim 1,
wherein the first electrode is an anode electrode, and
the second electrode is a cathode electrode.

11. The display device according to claim 1,
wherein the arrangement pattern of the sub-pixels is selected from a group consisting of a stripe shape, a matrix shape, a delta shape, and a combination of the stripe shape and the matrix shape.

12. The display device according to claim 1,
wherein an end surface of the second electrode and an end surface of the organic compound layer form a continuous surface.

13. The display device according to claim 1,
wherein two or more types of sub-pixels are provided as the sub-pixels, and
an end surface of the second electrode and an end surface of the organic compound layer form a continuous surface for each type of the sub-pixels.
